(19) United States
(12) Patent Application Publication
(10) Pub. No.: US 2017/0204514 A1
(43) Pub. Date: Jul. 20, 2017

(54) CVD PROCESS CHAMBER COMPONENT HAVING ALUMINUM FLUORIDE BARRIER FILM THEREON

(71) Applicants: Ok Ryul KIM, Yongin-si (KR); Ok Min KIM, Yongin-si (KR); FEMVIX CORP., Yongin-si (KR)

(72) Inventors: Ok Ryul KIM, Yongin-si (KR); Ok Min KIM, Yongin-si (KR)

(21) Appl. No.: 15/327,837

(22) PCT Filed: Mar. 27, 2015
(86) PCT No.: PCT/KR2015/003041

§ 371 Date: Jan. 20, 2017

(30) Foreign Application Priority Data
Aug. 8, 2014 (KR) 10-2014-0102155

(51) Int. Cl. C23C 16/22; C23C 16/455

(52) U.S. Cl. CPC C23C 16/22; C23C 16/455

(57) ABSTRACT

Provided is a chemical vapor deposition (CVD) process chamber component located in a CVD process chamber, wherein the component is a three-dimensional object including a material containing an aluminum element, an aluminum fluoride (AlF₃) barrier film with no crack is formed along a three-dimensional surface of the component, and the aluminum fluoride barrier film is formed by spraying and coating ceramic powder including yttrium (Y) or including any one of SiC, ZrO₂, ZrC, TiO₂, TiN, TiC, TiCN, TiCl₂, and HfO₂ on a surface of the component without being separated from a corner and a surface of the component.

### TECHNICAL FIELD

The present invention relates to a component located in the interior of a chemical vapor deposition (CVD) process chamber. In detail, the present invention relates to a CVD process chamber component having an aluminum fluoride barrier film thereon, which prevents aluminum fluoride (AlF₃) from being generated when fluorine contained in gases, such as CIF₃, CF₄, and NF₃, used for cleaning the interior of the process chamber is bonded to aluminum elements constituting the component.

### BACKGROUND ART

The present invention relates to a process chamber component for performing a chemical vapor deposition (CVD) process.

In general, process chamber components used for a process chamber for performing a CVD process include a heater, a showerhead, a susceptor, a process chamber inner wall, a baffle, an electrode, a power terminal, a flange, a screw, a bar, a heater support, and a bracket.

For example, when silicon dioxide (SiO₂) is deposited on a wafer disposed in a process chamber in a CVD process, silicon dioxide is deposited on surfaces of the components in the process chamber, as well as on the wafer. Accordingly, in order to perform a continuous CVD process without changing deposition rate, a cleaning process for removing silicon dioxide that is deposited on the surfaces of the process chamber components after the deposition process is necessary.

Cleaning gases, such as CIF₃, CF₄, and NF₃ plasma, are used in a cleaning process of removing silicon dioxide deposited on the surfaces of the process chamber components, and then as aluminum constituting the process chamber components and fluorine contained in the cleaning gases are bonded to each other, aluminum fluoride (AlF₃) particles may be generated on the surfaces of the process chamber components.

Accordingly, because the aluminum fluoride (AlF₃) particles are accumulated in the wafer or attached to the process components, yield rate decreases as a continuous CVD process cannot be performed, and an ex-situ cleaning process for the process chamber components has to be continuously and frequently performed. That is, if deposition rate changes due to the particles and side-products generated as the number of accumulated wafers increases during a CVD process, the CVD process has to be stopped and the process chamber components have to be repeatedly cleaned at a short cycle or have to be replaced by new components.

The conventional technologies for dealing with the problems are as follows.

U.S. Pat. No. 6,379,492 (entitled “Corrosion Resistant Coating”) relates to a technology of protecting the heater from a CVD process environment by coating magnesium fluoride on a surface of an aluminum nitride (AlN) that is a process component located in a CVD process chamber through chemical vapor deposition or physical vapor deposition (PVD). Meanwhile, a thin film having a coating film thickness of 2 μm or less (preferably, 1 μm or less) has to be maintained such that the coating film is not separated from a surface of an aluminum nitride heater so that a crack is not generated in a plasma environment of a high temperature of not less than 550° C., which contains fluorine. Further, when a coating film having a thickness of 2 μm or more is formed on a surface of the aluminum nitride heater, an aluminum element constituting a heater may be bonded to a fluorine element contained in the cleaning gas through the crack of the coating film so that aluminum fluoride (AlF₃) particles may be generated. In particular, because a crack may be generated if the coating films of a corner portion of the heater, a lift pin hole, and portions around the holes have the same thickness as that of the planar coating film even though the thickness of the coating film of the planar surface of the heater is maintained at 2 μm or less, the thickness of the coating films at the portions has to be further reduced. However, the thickness of the thin film has to be made extremely small to prevent a crack, and due to the small thickness of the thin film, it becomes more difficult to continuously protect the process components from the process environment.

Korean Patent No. 10-1037189 (entitled “Large-area Showerhead for Plasma Chemical Vapor Deposition device”) and Korean Patent No. 10-1300127 (entitled “Showerhead and Method for Manufacturing the Same”) relate to a technology for restraining particles from being generated during a process by forming a coating film through a CVD method and a sol-gel or CVD method. Meanwhile, as in U.S. Pat. No. 6,379,492 (entitled “Corrosion Resistant Coating”), because a crack may be generated at the corners, in the holes, or around the holes of the showerhead, it is difficult to protect the process components from the process environment and AlF₃ particles may be generated.

Korean Patent No. 10-1228056 (entitled “Ceramic Coating Metal Susceptor and Method for Manufacturing the Same”) relates to a ceramic coating metal susceptor for heating a wafer in a CVD process. According to the technology, a nickel containing buffer layer of a porosity of 12% functioning to absorb thermal stresses between a ceramic layer and a metal plate body is spray-coated on outer surfaces of the metal plate body and a metal support shaft to have a thickness of 50 μm, by using a plasma spray device, and an alumina corrosion preventing ceramic layer is spray-coated on the buffer layer to have a thickness of about 250 μm. Meanwhile, the technology uses a metal susceptor instead of using a susceptor of expensive aluminum nitride, and the problem is that because the thermal expansion and contraction of the metal susceptor due to the thermal expansion and contraction generated in an interface between a ceramic coating layer and the material layer of the susceptor is higher than the thermal expansion and contraction of the aluminum ceramic susceptor when the ceramic coating film is formed in an aluminum nitride ceramic material and the ceramic coating film is formed in a metal material, the coating film may be separated at a high temperature of 550° C. or more. However, it is difficult to basically solve the problem even there is provided a buffer layer. Further, as the technology essentially causes pores and cracks in the coating film as it uses a spray coating method, fluorine contained in the cleaning gas is bonded to aluminum through the pores and cracks during the CVD process to generate aluminum fluoride (AlF₃) particles, contaminating the interior of a process chamber, a process component, and a wafer.

Korean Patent No. 10-0839928 (entitled “Heater having Alumina Coating Layer and Method for Manufacturing the Same”) relates to a heater having an alumina coating layer that allows in-situ cleaning at a high temperature by diffusing and coating aluminum on a surface of the heater of a nickel substrate through coating methods, such as pack cementation and vapor phase deposition (VPD), and forming an alumina layer (NiAl₂O₃) through heat treatment to prevent the metal heater used to supply heat to a wafer during a semiconductor manufacturing process from corroding due to fluorine. The technology forms a NiAl₂O₃ coating film instead of aluminum nitride in the metal heater, but aluminum of the coating film and fluorine contained in the cleaning gas may be bonded to each other, generating AlF₃ particles.

Korean Patent Application No. 10-2012-0069285 (entitled “Cleaning Apparatus of AlN Heater for Semiconductor Manufacturing Equipment and Cleaning Method”) relates to a technology of removing aluminum fluoride (AlF₃) generated in an AlN heater by an NF₃ gas used to cleaning a chamber after the semiconductor manufacturing process, by using N₂ plasma. That is, if a thin film deposition process progresses while the extracted aluminum fluoride (AlF₃) is left on the heater, aluminum fluoride (AlF₃) is introduced into the wafer while becoming particles, causing deterioration of the semiconductor device, and accordingly, the thickness of the thin film change while the dielectric characteristics of the AlN heater changes and the technology is adapted to solve the problem. However, the technology is a technology for removing AlF₃ after AlF₃ is generated in the interior of the process chamber, but is not a basic measure for preventing generation of AlF₃ particles.

Korean Patent Application No. 10-2012-7019028 (entitled “Gas Distribution Showerhead with Coating Material for Semiconductor Processing”; PCT/US2001/022418; US 2011/0198034 “Gas Distribution Showerhead With Coating Material for Semiconductor Processing”) and Korean Patent Application No. 10-2013-7006943 (entitled “Gas Distribution Showerhead With High Emissivity Surface”; PCT/US2011/039857; US 2012/0052216 “Gas Distribution Showerhead with High Emissivity Surface”) relate to a technology of forming a coating film on a showerhead process component used in a CVD process through spray of plasma (thermal spray), and because pores and cracks are generated in the coating film, aluminum and fluorine contained in the cleaning gas are bonded to each other through the pores and cracks of the process component coating film, generating aluminum fluoride particles and causing arcing in the pores and cracks.

Further, Korean Patent Application No. 10-2011-7029814 (entitled “Anodized Showerhead”; PCT/US2010/034806; US 2010/0288197 “Anodized Showerhead”) relates to a technology of anodizing a showerhead that is a CVD process component. However, because the anodized surface of the showerhead has pores and cracks, aluminum of the aluminum showerhead and fluorine contained in the cleaning gas may be bonded to each other, generating aluminum fluoride particles.

Meanwhile, an aerosol deposition (AD) method may be considered as a ceramic coating film manufacturing method for protecting various process components located in the interior of process equipment for performing a CVD process from a process environment and restraining accumulation of contaminants and particles generated on a surface of the component during a process, and according to the aerosol deposition (AD) method, it is difficult to form a coating film of a uniform thickness on a surface of the process component, and in particular, it is difficult to apply the aerosol deposition method because a coating film is separated from a stepped area, a corner, or a vicinity of a hole.

Accordingly, it is necessary to prevent generation of AlF₃ particles during the CVD process by forming an aluminum-fluorine bonding preventing film on a surface of the process component applied to the CVD process and to prevent a coating film from being separated from a corner, a surface, a hole, and a convexo-concave portion of a three-dimensional body of the process component. Accordingly, the present invention provides a CVD process chamber component having an aluminum fluoride barrier film thereon, which may be continuously used without any change in deposition rate until the accumulated number of wafers reaches 12,000 or more, unlike a conventional CVD process component that shows a change in deposition rate if the accumulated number of wafers reaches 3,000 to 6,000.

### DISCLOSURE

### Technical Problem

An objective of the present invention is to provide a CVD process chamber component having an aluminum fluoride barrier film thereon. Accordingly, the present invention is directed to contributing to extending a life span and an ex-situ cleaning period of a process chamber component and improving the productivity and yield rate of a semiconductor substrate. In particular, the present invention provides a CVD process chamber component having an aluminum fluoride barrier film thereon, which may be continuously used without any change in deposition rate until the accumulated number of wafers reaches 12,000 or more, unlike a conventional CVD process component that shows a change in deposition rate if the accumulated number of wafers reaches 3,000 to 6,000.

### Technical Solution

In accordance with an aspect of the present invention, there is provided a chemical vapor deposition (CVD) process chamber component located in a CVD process chamber, wherein the component is a three-dimensional object including a material containing an aluminum element, an aluminum fluoride (AlF₃) barrier film with no crack is formed along a three-dimensional surface of the component, and the aluminum fluoride barrier film is formed by spraying and coating ceramic powder including yttrium (Y) or including any one of SiC, ZrO2, ZrC, TiO₂, TiN, TiC, TiCN, TiCl₂, and HfO₂ on a surface of the component without being separated from a corner and a surface of the component.

Then, the component may be configured such that the aluminum fluoride barrier film is not separated from a hole and a convexo-concave portion of the component.

Further, the aluminum fluoride barrier film may be formed by spraying and coating the ceramic powder at a temperature of 0 to 50° C. and in a vacuum state.

Further, the aluminum fluoride barrier film may comprise a ceramic crystal domain or a ceramic crystal domain and a ceramic non-crystal domain are mixed in the aluminum fluoride barrier film.

Further, the aluminum fluoride barrier film may have no pore.

Further, the aluminum fluoride barrier film may be polished to have a surface roughness (Ra) of 0.01 to 5 μm.

Further, the aluminum fluoride barrier film may have a thickness of 3 to 10 μm.

Further, the aluminum fluoride barrier film may not be separated when the component is thermally expanded or contracted during the CVD process.

Further, the components may comprise any one of a heater, a showerhead, a susceptor, a process chamber inner wall, a baffle, an electrode, a power terminal, a flange, a screw, a bar, a heater support, and a bracket.

Further, ceramic powder introduced into a gas suction pipe by a negative pressure may be transported and sprayed through a spray nozzle in an environment, in which a transport gas in which a suction gas suctioned into the gas suction pipe communicated with a gas supply pipe and a supply gas provided from a gas supply unit to the gas supply pipe are mixed by the negative pressure in a coating chamber accommodating the spray nozzle coupled to a distal end of the gas supply pipe, is maintained in an atmospheric state so that the ceramic powder is sprayed and coated on a substrate (a CVD process chamber component) provided in the vacuumed coating chamber.

Further, the component may be formed of ceramic or a metal.

### Advantageous Effects

The effects of a CVD process chamber component having an aluminum fluoride barrier film thereon according to the present invention are as follows.

1. The present invention may basically prevent generation of aluminum fluoride (AlF₃) particles that are conventionally generated on a surface of a CVD process chamber.

2. The present invention may remarkably reduce by-products and particles attached to a surface of a component as compared with the case in which there is no aluminum fluoride barrier film.

3. The present invention may continuously use a process component of a CVD process until the accumulated number of wafers reaches 12,000 unlike a conventional CVD process that shows a change in deposition rate if the accumulated number of wafers reaches 3,000 to 6,000 or more.

4. The present invention increases a deposition speed of a CVD process, thereby improving productivity.

5. The present invention may extend the life span of a component by preventing the barrier film from being separated from a corner, a surface, a hole, and the vicinity of a hole of a three-dimensional body of a component and protecting the process component from a plasma cleaning gas by forming an aluminum fluoride barrier film on a surface of a component of the CVD process chamber such that the aluminum fluoride barrier film has a thickness of 3 to 10 μm.

### DESCRIPTION OF DRAWINGS OF THE INVENTION

FIG. 1 is a schematic diagram of a CVD process chamber, to which a showerhead and a heater are mounted;

FIGS. 2 and 3 are schematic diagrams illustrating the showerhead exposed to an NF₃ plasma gas in the CVD process chamber;

FIG. 4 is a schematic diagram illustrating that AlF₃ particles generated by bonding fluorine contained in a cleaning gas in the process chamber and aluminum contained in an aluminum nitride heater are stuck to surfaces of the heater after chemical vapor deposition;

FIG. 5 is a schematic diagram illustrating an example in which aluminum fluoride barrier films are formed at portions (an upper surface, a side surface, a lower surface, a shaft, and a mount) of the surfaces of the heater that is one of CVD process chamber components;

FIG. 6 is a schematic diagram illustrating that AlF₃ particles generated by bonding fluorine contained in a cleaning gas in the process chamber and aluminum contained in an aluminum showerhead are stuck to surfaces of the showerhead and then drop to a wafer after chemical vapor deposition;

FIG. 7 is a schematic diagram illustrating that aluminum fluoride barrier films are formed on the surfaces of the showerhead that is one of the CVD process chamber components; and

FIG. 8 is a schematic diagram illustrating a ceramic coating apparatus for manufacturing a CVD process chamber component having an aluminum fluoride barrier film thereon according to the present invention.

The reference numerals of the drawings are as follows.
10: Upper surface of heater
11: Upper surface of heater having aluminum fluoride barrier film thereon
12: Embossed portion on upper surface of heater
13: Lift pin hole
20: Side surface of heater
21: Aluminum fluoride barrier film formed on side surface of heater
30: Lower surface of heater
31: Aluminum fluoride barrier film formed on lower surface of heater
40: Shaft of heater
41: Aluminum fluoride barrier film formed on surface of shaft of heater
50: Mount of heater
51: Aluminum fluoride barrier film formed on surface of mount of heater
61: AlF₃ particles
62: Aluminum fluoride barrier film
63: Gas hole
70: Wafer
80: Gas supply unit
81: Pressure adjusting unit
82: Flow rate adjusting unit
83: Gas supply pipe
84: Gas suction pipe
85: Pressure/temperature gauge
86: Spray nozzle
87: Location control unit
88: Substrate holder
89: Substrate (CVD process chamber component)
90: Coating chamber
91: Suction gas
92: Supply gas
93: Ceramic powder (solid powder)
94: Transport gas
100: Heater
200: Showerhead
300: NF₃ gas
400: Plasma
500: CVD process chamber

### BEST MODE

The best form of a CVD process chamber component having an aluminum fluoride barrier film thereon according to the present invention is as follows.

The component is located in a chemical vapor deposition (CVD) process chamber and a three-dimensional object formed of a material containing an aluminum element, and an aluminum fluoride (AlF₃) barrier film with no crack and pore is formed along a three-dimensional surface of the component, the aluminum fluoride barrier film is formed by spraying and coating ceramic powder including yttrium (Y) or including any one of SiC, ZrO₂, ZrC, TiO₂, TiN, TiC, TiCN, TiCl₂, and HfO₂ on the surfaces of the process component, and the ceramic power is not separated from a corner, a surface, a hole, and a convexo-concave portion of the component while or after the ceramic powder is sprayed and coated.

Further, the aluminum fluoride barrier film is made to have a surface roughness (Ra) of 0.01 to 5 μm by spraying and coating the ceramic powder with a thickness of 3 to 10 μm at a temperature of 0 to 50° C. and in a vacuum state and then polishing the ceramic powder, and the aluminum fluoride barrier film may include a ceramic crystal domain or a ceramic crystal domain and a ceramic non-crystal domain are mixed in the aluminum fluoride barrier film.

Hereinafter, a CVD process chamber component having an aluminum fluoride barrier film thereon and a method for forming an aluminum fluoride barrier film on the CVD process chamber component will be described in detail with reference to the accompanying drawings.

I. CVD Process Chamber Component Having Aluminum Fluoride Barrier Film Thereon

The present invention relates to a component located in the interior of a chemical vapor deposition (CVD) process chamber 500. A surface of the component includes aluminum, and aluminum fluoride particles (AlF₃) are generated when fluorine contained in gases, such as ClF₃, CF₄, and NF₃, used for cleaning the interior of the process chamber 500 are bonded to an aluminum element of the component. The present invention provides a CVD process chamber component having an aluminum fluoride barrier film thereon, which may be continuously used without any change in deposition rate until the accumulated number of wafers reaches 12,000 or more by forming an aluminum fluoride barrier film along a three-dimensional surface of the component to prevent generation of the aluminum fluoride particles, unlike a conventional CVD process component that shows a change in deposition rate if the accumulated number of wafers reaches 3,000 to 6,000.

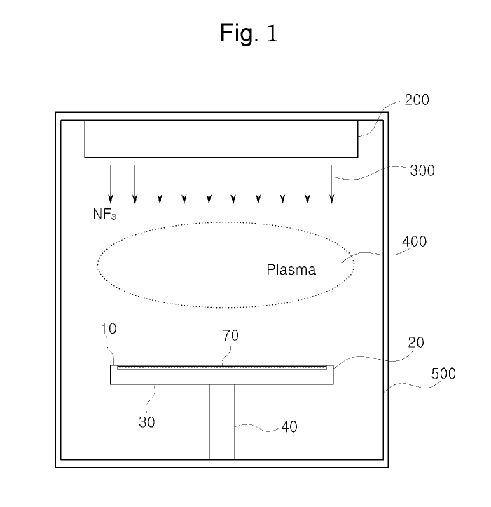

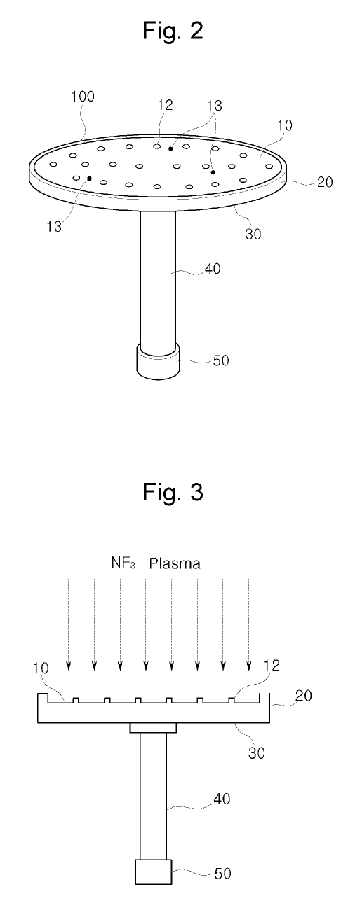

The component is a component located in the CVD process chamber 500, and as illustrated in FIG. 1, includes a heater 100, a showerhead 200, a susceptor, a baffle, an electrode, a power terminal, a flange, a screw, a bar, a heater support, a bracket, and a process chamber inner wall.

The material of the component is ceramic or a metal containing an aluminum element. The ceramic material including the aluminum element may be alumina (Al₂O₃) or aluminum nitride (AlN), of which the thermal conductivity is about five times as high as that of alumina (Al₂O₃), and may be a metal containing the aluminum element, such as aluminum or Inconel. Inconel is a heat-resistant alloy in which 15% of chromium, 6 to 7% of iron, 2.5% of titanium, and not more than 1% of aluminum, and manganese silicon are added to nickel that is a main element. Inconel is heat-resistant, and is not oxidized even in an oxidation air flow of 900° C. or higher and is not immersed even in the atmosphere containing sulfur.

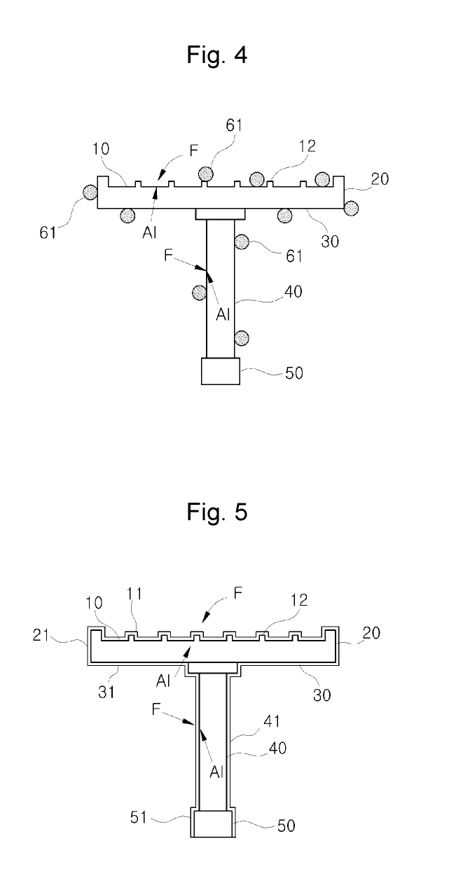

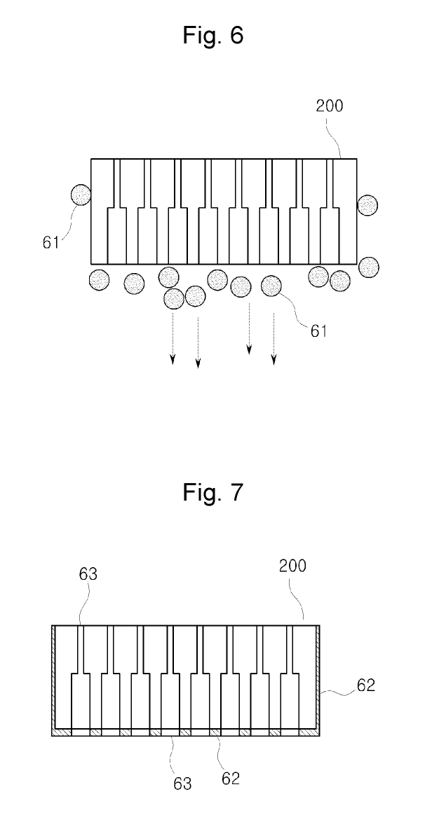

As illustrated in FIGS. 1 and 3, the component is exposed to plasma including fluorine in the CVD process chamber. Accordingly, when there is no aluminum fluoride barrier film on a surface of the component, as in the examples of FIGS. 4 and 6, aluminum fluoride (AlF₃) particles are generated.

As in the examples of the schematic diagrams of FIGS. 5 and 7, the aluminum fluoride barrier film is formed along a three-dimensional surface of the component including aluminum without generating a pore and a crack, and in particular, is prevented from being separated from portions, such as a corner, a surface, and a hole of the component. In detail, when ceramic powder is coated in an aerosol deposition (AD) method, a film separation phenomenon is generated at a portion, such as a corner, a hole, and a convexo-concave portion of the component, along a three-dimensional surface of the component during and after coating. However, when ceramic powder is sprayed and coated at a temperature of 0 to 50° C. and in a vacuum state according to the present invention, a film separation phenomenon is not generated even at a portion, such as a corner, a surface, a hole, and a convexo-concave portion of the component, which is not flat along the three-dimensional surface of the component, while and after the ceramic powder is coated.

In this way, the aluminum fluoride barrier film is not separated even when the component is thermally expanded or contracted due to the CVD process.

The aluminum fluoride barrier film includes a ceramic crystal domain or a ceramic crystal domain and a ceramic non-crystal domain are mixed in the aluminum fluoride barrier film. Further, the aluminum fluoride barrier film may have a thickness of 3 to 10 μm, and may be polished to have a surface roughness (Ra) of 0.01 to 5 μm. Further, the ceramic forming the barrier film may include yttrium (Y) or may include any one of SiC, ZrO₂, ZrC, TiO₂, TiN, TiC, TiCN, TiCl₂, and HfO₂. The example of ceramic including yttrium (Y) includes Y₂O₃, YF₃, and YSZ (Y₂O₃ stabilized ZrO₂).

Hereinafter, a method for forming the aluminum fluoride barrier film will be described in detail.

II. Method for Forming Aluminum Fluoride Barrier Film on CVD Process Component

The aluminum fluoride barrier film is formed by spraying and coating ceramic powder including yttrium (Y) or including any one of SiC, ZrO₂, ZrC, TiO₂, TiN, TiC, TiCN, TiCl₂, and HfO₂ on a surface of the component without generating a pore or a crack and without being separated while and after the ceramic powder is coated.

The CVD process chamber component having an aluminum fluoride barrier film thereon according to the present invention may be manufactured by applying a solid powder coating method in which ceramic powder 93 introduced into a gas suction pipe 84 by a negative pressure is transported and sprayed through a spray nozzle 86 in an environment, in which a transport gas 94 in which a suction gas 91 suctioned into the gas suction pipe 84 communicated with a gas supply pipe 83 and a supply gas 92 provided from a gas supply unit 80 to the gas supply pipe 83 are mixed by the negative pressure in a coating chamber 90 accommodating the spray nozzle 86 coupled to a distal end of the gas supply pipe 83 so that the ceramic powder 93 is sprayed and coated on a substrate 89 (a CVD process chamber component) provided in the vacuumed coating chamber 90.

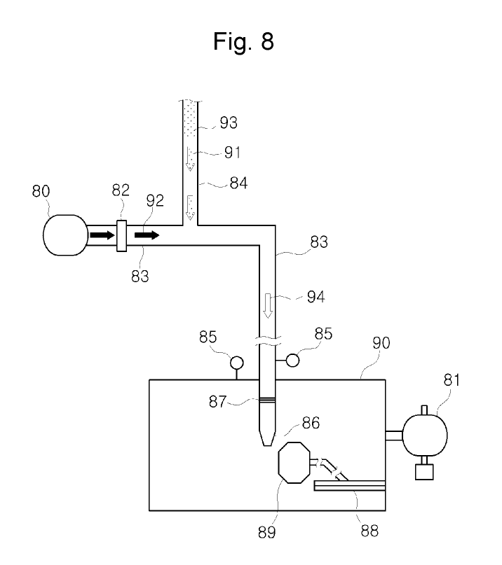

Further, the ceramic powder coating method may be implemented by a ceramic powder coating apparatus including, as illustrated in FIG. 8, a gas supply pipe 83 functioning as a passage of a supply gas supplied by a gas supply unit 80 and having a distal end, to which a spray nozzle 86 is coupled, a gas suction pipe 84 communicated with the gas supply pipe 83 while one side thereof is opened to the atmosphere; a ceramic powder supply unit (not illustrated) configured to supply ceramic powder 93 accommodated in an environment in which the atmospheric state is maintained to the gas suction pipe 84; a coating chamber 90 accommodating the spray nozzle 86; a flow rate adjusting unit 82 configured to adjust an internal pressure of the gas supply pipe 83; and a pressure adjusting unit 81 configured to adjust an internal pressure of the coating chamber 90, wherein the ceramic powder 93 is introduced from the ceramic powder supply unit (not illustrated) to the gas suction pipe 84 by a negative pressure of the coating chamber 90 formed through driving of the pressure adjusting unit 81, and acts as the transport gas 94 of the ceramic powder 93 together with the suction gas 91 suctioned into one opened side of the gas suction pipe 84 and the supply gas 92 supplied from the gas supply unit 80, and wherein ceramic powder is sprayed and coated on a substrate 89 (a process component) disposed in the vacuumed coating chamber 90.

The contents on the ceramic powder coating method and the ceramic coating apparatus are described in detail in Korean Patent Application No. 10-2014-0069017 (entitled “Solid Powder Coating Apparatus and Coating Method”) and Korean Patent Application No. 10-2013-0081638 (PCT/KR2014/006217 “Powder Coating Apparatus And Method”).

Although the present invention has been described with reference to the accompanying drawings, it may be corrected and modified without departing from the spirit of the present invention and may be used in various fields. Accordingly, the claims of the present invention include corrections and modifications that pertain to the genuine scope of the present invention.

### INDUSTRIAL APPLICABILITY

The present invention relates to a component located in the interior of a chemical vapor deposition (CVD) process chamber. In detail, the present invention relates to a CVD process chamber component having an aluminum fluoride barrier film thereon, which prevents aluminum fluoride (AlF₃) from being generated when fluorine contained in gases, such as CIF₃, CF₄, and NF₃, used for cleaning the interior of the process chamber is bonded to aluminum elements constituting the component, and thus is industrially applicable.

1. A chemical vapor deposition (CVD) process chamber component located in a CVD process chamber, wherein the component is a three-dimensional object including a material containing an aluminum element, an aluminum fluoride (AlF₃) barrier film with no crack is formed along a three-dimensional surface of the component, and the aluminum fluoride barrier film is formed by spraying and coating ceramic powder including yttrium (Y) or including any one of SiC, ZrO₂, ZrC, TiO₂, TiN, TiC, TiCN, TiCl₂, and HfO₂ on a surface of the component without being separated from a corner and a surface of the component, and the aluminum fluoride barrier film is formed by spraying and coating the ceramic powder at a temperature of 0 to 50° C. and in a vacuum state.

2. The CVD process component of claim 1, wherein the component is configured such that the aluminum fluoride barrier film is not separated from a hole and a convexo-concave portion of the component.

3. (canceled)

4. The CVD process component of claim 1, wherein the aluminum fluoride barrier film comprises a ceramic crystal domain or a ceramic crystal domain and a ceramic non-crystal domain are mixed in the aluminum fluoride barrier film.

5. The CVD process component of claim 1, wherein the aluminum fluoride barrier film has no pore.

6. The CVD process component of claim 1, wherein the aluminum fluoride barrier film is polished to have a surface roughness (Ra) of 0.01 to 5 μm.

7. The CVD process component of claim 1, wherein the aluminum fluoride barrier film has a thickness of 3 to 10 μm.

8. The CVD process component of claim 1, wherein the aluminum fluoride barrier film is not separated when the component is thermally expanded or contracted during the CVD process.

9. The CVD process component of claim 1, wherein the components comprises any one of a heater, a showerhead, a susceptor, a process chamber inner wall, a baffle, an electrode, a power terminal, a flange, a screw, a bar, a heater support, and a bracket.

10. The CVD process component of claim 1, wherein ceramic powder (93) introduced into a gas suction pipe (84) by a negative pressure is transported and sprayed through a spray nozzle (86) in an environment a transport gas (94) in which a suction gas (91) suctioned into the gas suction pipe (84) communicated with a gas supply pipe (83) and a supply gas (92) provided from a gas supply unit (83) to the gas supply pipe (80) are mixed by the negative pressure in a coating chamber (90) accommodating the spray nozzle (86) coupled to a distal end of the gas supply pipe (83) is maintained in an atmospheric environment so that the ceramic powder (93) is sprayed and coated on a substrate (89) (a CVD process chamber component) provided in the vacuumed coating chamber (90).

11. The CVD process chamber component of claim 1, wherein the component is formed of ceramic or a metal.
